(19) United States
(12) Patent Application Publication
(10) Pub. No.: US 2011/0267050 A1
(43) Pub. Date: Nov. 3, 2011

(54) MAGNETIC STUD FINDER

(76) Inventor: ROBERT L. FLORES, Houston, TX (US)

(21) Appl. No.: 12/771,427

(22) Filed: Apr. 30, 2010

(51) Int. Cl. G01R 33/02

(52) U.S. Cl. 324/259

(57) ABSTRACT

A magnetic apparatus for locating hidden ferrous fasteners includes a holder of a preselected non-ferromagnetic material having a base member and at least one wall member of a first predetermined height. The wall member being fixed substantially normal to the base member and has a perimeter about 30 to 70% of a perimeter of the base member. The apparatus further includes a cylindrical magnet of preselected type having a predetermined diameter and a second predetermined height and having sufficient strength to pull itself to such hidden ferrous fastener across a separation distance of at least ½-inch.

### FIELD OF THE INVENTION

The present invention relates, in general, to devices for locating wall studs and, more particularly, this invention relates to a simple magnetic device and method for locating nails in studs.

### BACKGROUND OF THE INVENTION

Prior to the conception and development of the present invention, homeowner's and craftsmen working on existing walls in houses have sought the ideal apparatus for locating the studs behind drywall or in ceilings. Numerous magnetic devices have been proposed and put into use, all with one or more drawbacks which the present invention overcomes. Bray in U.S. Pat. No. 2,933,679 and Shiao in U.S. Pat. No. 6,087,824 disclose magnetic stud finders that utilize an elongated magnet that can pivot on a central radial portion within a handheld device that is slid along a wall. When the magnet gets near a nail behind the surface of the wall, it pivots with an end of the magnet pointing towards the nail. When right above the nail head, the magnet aligns perpendicular to the wall, and the wall location must be marked with an instrument in one hand while the other hand holds the device against the wall. Thus it takes two hands and a marking instrument to operate these types of units.

In U.S. Pat. No. 6,229,294, Wun discloses a magnetic stud locator that has a magnet on a string swing like a pendulum from a hand-held portion until the magnet gets close to a nail and sticks right above it. A similar detector was disclosed by Rowley in U.S. Pat. No. 6,456,053. The main drawback with Wun and Rowley is that they will not work on a ceiling. Another is the limited range of wall surface the magnet traverses searching for the nail. If one starts with the hand-held portion equidistant from two studs, it may not locate a nail for a long time.

In U.S. Pat. No. 7,183,885, Nellessen, Sr. et al discloses a magnetic ferrous object locator that also has a magnetic V at one end to hold a fastener that can be driven into the accompanying stud once it is located. However, locating the stud can be a slow and tedious process, and if the wall surface is rough, the object locator may not slide easily. And if the user moves it too quickly, they may not detect the hidden ferrous object beneath the surface being scanned. Also, the Nellessen, Sr. et al locator may not center itself directly over the hidden ferrous object.

### SUMMARY OF THE INVENTION

The present invention provides a magnetic apparatus for locating hidden ferrous fasteners, the apparatus consisting of a holder of preselected non-ferromagnetic material having a base member and at least one wall member of a first predetermined height, the wall member being fixed substantially normal to the base member and having a perimeter about 30 to 70% of a perimeter of said base member and further including a cylindrical magnet of preselected type having a predetermined diameter and a second predetermined height and having sufficient strength to pull itself to such hidden ferrous fastener across a separation distance of at least ½-inch.

In a preferred embodiment, the holder has a semi-cylindrical wall member attached to top and bottom disks with an opening in the wall member of at least 33% of the perimeter. A cylindrical neodymium (NIB) magnet rests in the holder until pulled magnetically to a hidden fastener in a wall or ceiling.

### OBJECTS OF THE INVENTION

It is, therefore, one of the primary objects of the present invention to provide a cost-effective device for locating studs in both walls and ceilings.

Another object of the present invention is to provide a simple and effective device for locating invisible nails in studs with provisions for easily marking the edges of a stud.

Still another object of the present invention is to provide a stud-finder apparatus that can place multiple stud location markers along a ceiling stud.

Yet another object of the present invention is to provide a stud locating device that will leave a magnetic marker on the wall or ceiling while the holding unit is still in motion.

An additional object of the present invention is to provide a stud location marker that readily centers itself over the hidden ferrous object beneath the surface.

In addition to the various objects and advantages of the present invention described with some degree of specificity above, it should be obvious that additional objects and advantages of the present invention will become more readily apparent to those persons who are skilled in the relevant art from the following more detailed description of the invention, particularly, when such description is taken in conjunction with the attached drawing figures and with the appended claims.

### BRIEF DESCRIPTION OF THE DRAWINGS

FIG. 1 provides a perspective view of the present invention in a first stage of use.

FIG. 2 is a perspective view of the present invention in a second stage of usage.

FIG. 3 provides a perspective view of a preferred embodiment of the holder portion of the present invention.

FIG. 4 is a perspective view of an alternative embodiment of the present invention.

FIG. 5 is a sectional top plan view of the present invention in a stage of usage.

FIG. 6 provides a perspective view of an alternative type of magnetic cylinder.

### DETAILED DESCRIPTION OF A PRESENTLY PREFERRED AND VARIOUS ALTERNATIVE EMBODIMENTS OF THE INVENTION

Prior to proceeding to the more detailed description of the present invention it should be noted that, for the sake of clarity and understanding, identical components which have identical functions have been identified with identical reference numerals throughout the several views illustrated in the drawing figures.

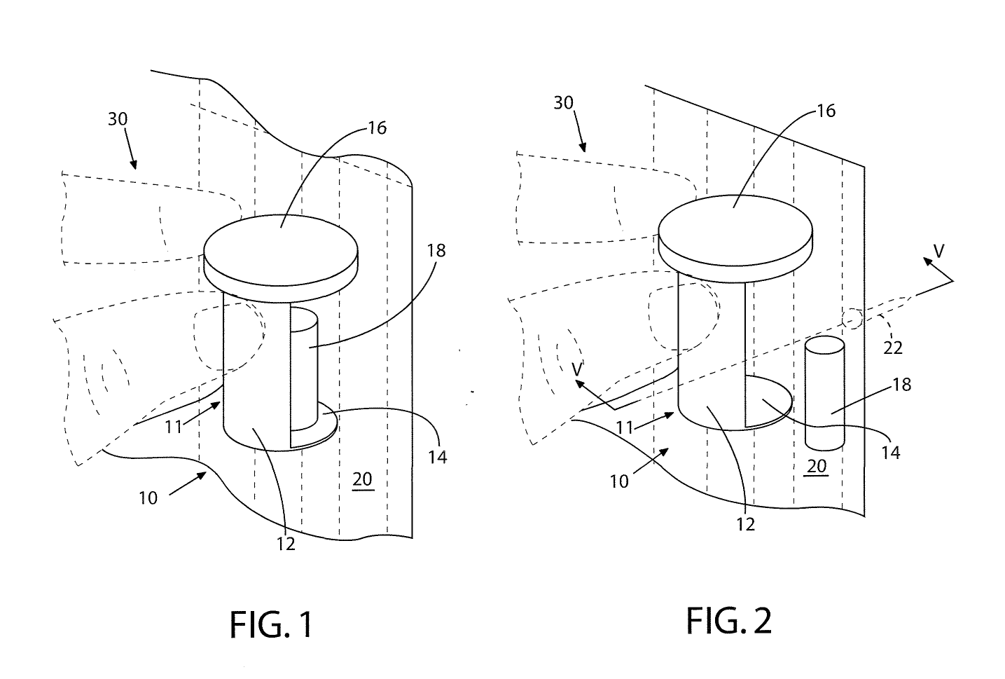

Referring initially to FIG. 1, a perspective view of the present invention, generally shown as 10, in a first stage of use is provided. A cylindrical magnet 18, typically a right circular cylinder, is loosely supported in a holder 11, the holder consisting of a substantially planar base member 14, a top member 16, and a sidewall 12 enclosing a portion of the space between the base and top members. The material of construction for the holder must be non-ferromagnetic, but otherwise can be plastic, glass, wood, or one of certain metals such as aluminum. Typically, the sidewall 12 encloses no more than about half of the perimeter of the base and top members. The magnet 18 is supported from falling by the base member 14, but it can slide reading along the surface of the base member 14 when attracted by a ferromagnetic item in the vicinity. Preferably, the base and top members are round to permit easy sliding of the holder 11 as it is swiped along a wall 20. While a top member is preferred, it is not essential. The holder can be just the base member 14 and side wall 12.

FIG. 2 is a perspective view of the present invention in a second stage of usage. While the holder 11 is still in motion by the action of a user's hand 30, the magnet 18 has “jumped” from the base member 14 to the wall 20 as a result of magnetic attraction between the strong magnet 18 and a ferromagnetic fastener 22 hidden behind the wall 20. In a short time thereafter, the top of the cylindrical magnet 18 will come to rest at the same level as the axis of the nail 22. The cylindrical magnet is preferably an NIB (neodymium alloy) type such as model D8×8 from K & J Magnetics. Certain AlNiCo alloy magnets can also be used, but are less preferred. The magnet should have a pull force of at least 10 pounds, and 12 to 16 pounds is preferred. Excessive pull force should be avoided. Many magnet sizes would function adequately, but preferably it is a solid right circular cylinder about ½ to ¾-inch diameter and 1.5 inches long. The magnet can alternatively have a radial aperture. The sidewall 12 of the holder 11 is sufficiently open on one side such that the holder 11 can pass over a magnet 18 sticking to a wall 20 without contacting and moving the magnet.

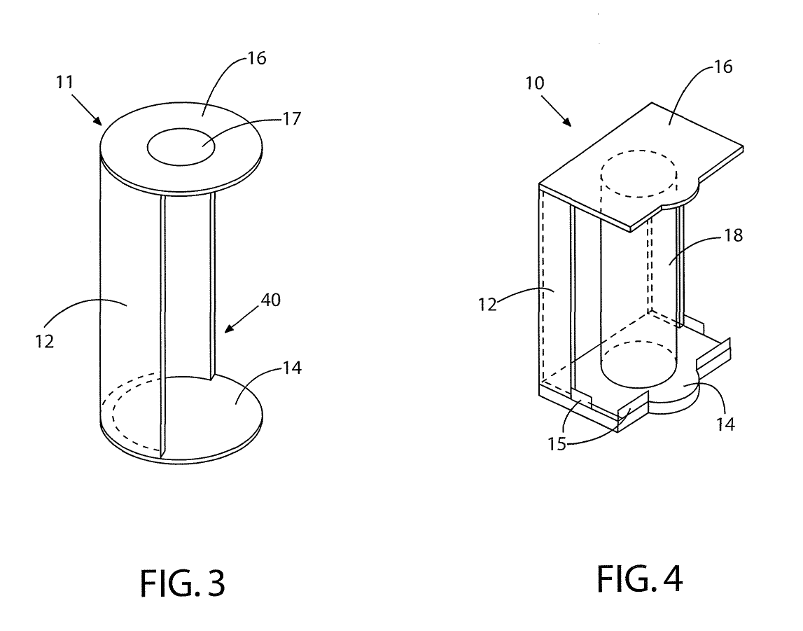

FIG. 3 provides a perspective view of a preferred embodiment of the holder 11 of the present invention. The base member 14 and the top member 16 are connected to opposite ends of a semi-cylindrical sidewall 12, preferably a portion of a hollow right circular cylinder cut longitudinally. There is an open area 40 between the parallel base member 14 and the top member 16. An optional aperture 17 in the top member 16 permits an alternative way to insert the magnet.

FIG. 4 is a perspective view of an alternative embodiment of the present invention, generally indicated by 10. In this embodiment, the base member 14 and the top member 16 are generally rectangular. Connecting the base and top members are side walls 12 that only partially enclose the space between the base and top members. A cylindrical magnet 18 rests inside with one end supported by the base member 14. Optional flexible flaps 15 may be positioned along the perimeter of the base member 14 to help prevent premature escape of the magnet, but still not inhibit the movement of the magnet toward a nail.

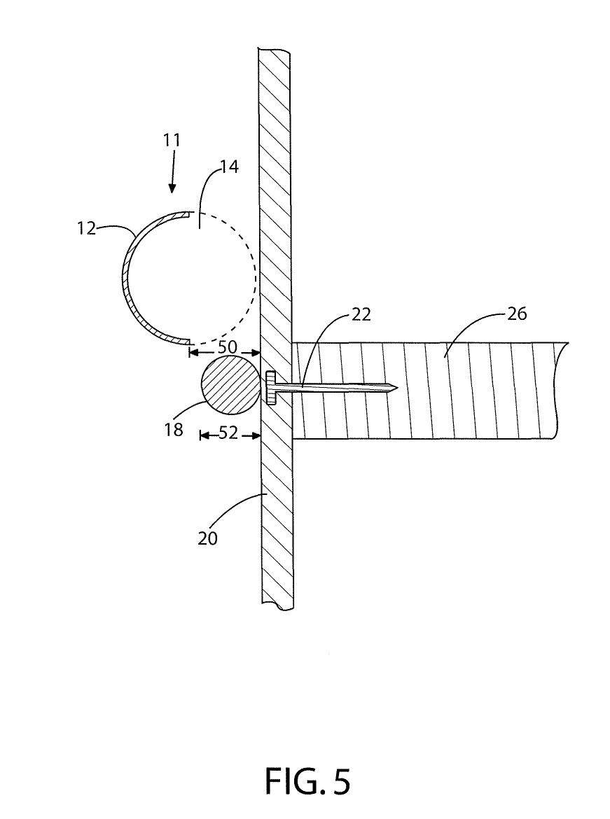

FIG. 5 is a sectional plan view taken along V-V in FIG. 2. This depicts the stage of use just after the magnet 18 has jumped from the base member 14 onto the wall 20 by the force of magnetic attraction to the nail 22 in a wall stud 26. The gap 50 between the wall 20 and the edge of the sidewall 12 is slightly greater than the diameter 52 of the magnet 18. This is so that as the holder 11 is slid along the wall 20 it will not drag the magnet 18 away from its position adjacent the nail 22. This significantly distinguishes the present invention from similar magnetic ones that require the user to notice when the magnet jumps to the wall, and then stop and lift the magnet holder.

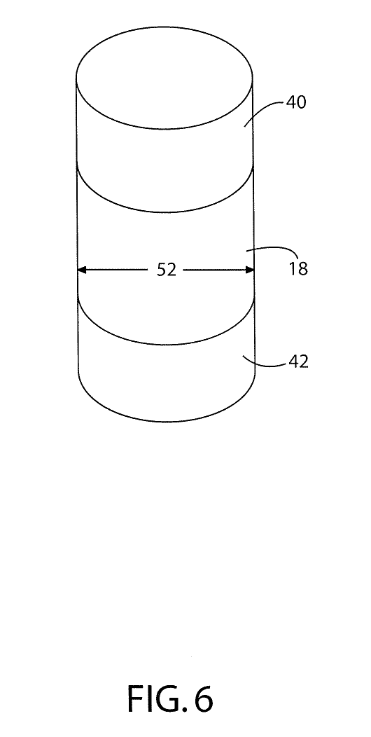

FIG. 6 provides a perspective view of an alternative type of magnetic cylinder. In this case, a magnetic cylinder having a diameter 52 is sandwiched between two steel cylinders 40 and 42 of similar diameter to provide the desired length with a lower-cost magnet. This arrangement may diminish the overall magnetic force somewhat, but the minimum pull force of 10 pounds can still be met when the central magnet has excess pull force, for instance, at least 20 pounds by itself.

While a presently preferred and various alternative embodiments of the present invention have been described in sufficient detail above to enable a person skilled in the relevant art to make and use the same, it should be obvious that various other adaptations and modifications can be envisioned by those persons skilled in such art without departing from either the spirit of the invention or the scope of the appended claims.

What is claimed is:

1. A magnetic apparatus for locating hidden ferrous fasteners comprising:
a) a holder of preselected non-ferromagnetic material having a base member and at least one wall member of a first predetermined height, said wall member fixed substantially normal to said base member and having a perimeter about 30 to 70% of a perimeter of said base member; and
b) a cylindrical magnet of preselected type having a predetermined diameter and a second predetermined height and having sufficient strength to pull itself to such hidden ferrous fastener across a separation distance of at least ½-inch.

2. The magnetic apparatus, according to claim 1, wherein said preselected non-ferromagnetic material is substantially rigid and one of plastic, wood, and ceramic.

3. The magnetic apparatus, according to claim 1, wherein said predetermined diameter is between about 0.5 and 0.75 inches.

4. The magnetic apparatus, according to claim 1, wherein said second predetermined height is between about 0.75 and 2.0 inches.

5. The magnetic apparatus, according to claim 1, wherein said first predetermined height is between about 1.0 and 2.5 inches.

6. The magnetic apparatus, according to claim 1, wherein said wall member is semi-cylindrical with a circumference less than half of 3.14 times its radius.

7. The magnetic apparatus, according to claim 1, wherein said preselected type of said cylindrical magnet is one of neodymium alloy and AlNiCo alloy.

8. A magnetic apparatus for locating hidden ferrous fasteners comprising:
a) a holding device of a preselected material having a base member, a top member and at least one wall member of a first predetermined height, said wall member being substantially normal to said top and base members and having an opening greater than one-third of a peripheral edge of each of said base and top members; and
b) a cylindrical neodymium magnet member having a predetermined diameter and a second predetermined height, wherein said magnet is removably engageable with said base member.

9. The magnetic apparatus, according to claim 8, wherein said preselected material is non-ferromagnetic.

10. The magnetic apparatus, according to claim 8, wherein said second predetermined height is between about 0.75 and 2.0 inches.

11. The magnetic apparatus, according to claim 8, wherein said first predetermined height is between about 1.0 and 2.5 inches.

12. The magnetic apparatus, according to claim 8, wherein said cylindrical neodymium magnet member is a right circular cylinder.

13. The magnetic apparatus, according to claim 8, wherein said cylindrical neodymium magnet member is a stack of a cylindrical neodymium magnet and at least one ferromagnetic cylinder.
